(19) United States
(12) Patent Application Publication
(10) Pub. No.: US 2024/0074236 A1
(43) Pub. Date: Feb. 29, 2024

(54) DISPLAY DEVICE

(71) Applicant: LG Display Co., Ltd, Seoul (KR)

(72) Inventors: Sunyoung CHOI, Seoul (KR); Dongchae SHIN, Goyang-si (KR); Sungjin LEE, Seoul (KR)

(73) Assignee: LG Display Co., Ltd, Seoul (KR)

(21) Appl. No.: 18/221,191

(22) Filed: Jul. 12, 2023

(30) Foreign Application Priority Data
Aug. 30, 2022 (KR) 10-2022-0109066

(51) Int. Cl. H10K 59/121; H10K 59/131; H10K 59/80

(52) U.S. Cl. CPC H10K 59/1213; H10K 59/1216; H10K 59/1315; H10K 59/8792

(57) ABSTRACT

A display device can include a first transistor disposed in a display area of a substrate, the first transistor including a first semiconductor layer, a first gate electrode, a first source electrode and a first drain electrode; a second transistor disposed a non-display area of the substrate, the second transistor including a second semiconductor layer, a second gate electrode, a second source electrode and a second drain electrode; and a first insulating layer disposed across the first oxide transistor and the second polycrystalline silicon transistor. Also, the display device can further include at least one capacitor disposed on the first insulating layer. Also, the first transistor can be an oxide transistor, the second transistor can be a polycrystalline silicon transistor, and the at least one capacitor can include a material configured to absorb hydrogen.

### CROSS-REFERENCE TO RELATED APPLICATION

This application claims priority, under 35 U.S.C. § 119, to Korean Patent Application No. 10-2022-0109066 filed in the Republic of Korea on Aug. 30, 2022, the contents of which in its entirety are herein incorporated by reference into the present application.

### BACKGROUND

### Field

The present disclosure relates to a display device, and more particularly, to a display device including a plurality of thin-film transistors that improve element reliability of the display device.

### Description of Related Art

Recent display devices capable of displaying various information and interacting with users who view the information have various sizes, various shapes, and various functions.

These display devices can include a liquid crystal display device (LCD), an electrophoretic display device (EPD), and an organic light-emitting diode display device (OLED).

The organic light-emitting diode display device is a self-luminous display device, and does not require a separate light source unlike the LCD, and thus can be manufactured in a lightweight and thin form. Moreover, the organic light-emitting diode display device is not only advantageous in terms of power consumption due to low voltage operation, but also is excellent in terms of color rendering, response speed, viewing angle, and contrast ratio (CR), and thus is being studied as a next-generation display.

The organic light-emitting diode display device controls current flowing through an organic light-emitting diode using a plurality of thin-film transistors (TFTs) to display an image.

Each of the plurality of thin-film transistors can be a thin-film transistor using a low-temperature polycrystalline silicon (LTPS) semiconductor pattern or a thin-film transistor using an oxide semiconductor pattern made of an oxide. Also, it can be difficult to manufacture an LTPS TFT and an oxide TFT together on a same substrate. For example, the channel of the oxide TFT can become damaged or impaired during the manufacturing process.

For example, when the thin-film transistor employs the oxide semiconductor pattern, a channel area of an oxide semiconductor can become conductive due to hydrogen and light generated internally or originated externally. Accordingly, the element characteristics can be degraded which can impair image quality and the lifespan of the device can be reduced.

### SUMMARY OF THE DISCLOSURE

A purpose to be achieved by the present disclosure is to provide a display device including different types of semiconductor patterns in which element characteristics of a transistor including an oxide semiconductor is stably secured.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display device according to an embodiment of the present disclosure can be provided. The display device includes a substrate including a display area and a non-display area disposed around the display area; a first transistor disposed in the display area and including a first semiconductor layer, a first gate electrode, a first source electrode, and a first drain electrode; a driver circuit area and a dam area disposed in the non-display area; a second transistor disposed in the driver circuit area and including a second semiconductor layer, a second gate electrode, a second source electrode, and a second drain electrode; a first insulating layer disposed on the first transistor and the second transistor; a first capacitor disposed in the display area; and a second capacitor disposed in the driver circuit area, in which the first capacitor includes a first capacitor electrode disposed on the first insulating layer, in which the second capacitor includes a second capacitor electrode disposed on the first insulating layer.

Details of other embodiments are included in the detailed descriptions and drawings.

In the display device using the thin-film transistors including different types of semiconductors according to the embodiment of the present disclosure, stability of the thin-film transistor including the oxide semiconductor can be secured, thereby improving display quality and extending the lifespan of the device.

In addition to the above effects, specific effects of the present disclosure are described together while describing specific details for carrying out the present disclosure.

Effects of the present disclosure are not limited to the effects mentioned above, and other effects not mentioned will be clearly understood by those skilled in the art from the descriptions below.

### BRIEF DESCRIPTION OF DRAWINGS

The above and other objects, features, and advantages of the present disclosure will become more apparent to those of ordinary skill in the art by describing example embodiments thereof in detail with reference to the attached drawings, which are briefly described below.

FIG. 1 is a block diagram of a display device according to an embodiment of the present disclosure.

FIG. 2 is a block diagram of a sub-pixel of a display device according to an embodiment of the present disclosure.

FIG. 3 is a cross-sectional view of a display device according to an embodiment of the present disclosure.

FIG. 4 is a cross-sectional view of a display device according to an embodiment of the present disclosure.

### DETAILED DESCRIPTION OF THE EMBODIMENTS

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included in the spirit and scope of the present disclosure as defined by the appended claims.

A shape, a size, a ratio, an angle, a number, etc. disclosed in the drawings for describing embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to,” or “connected to” another element or layer, it can be directly on, connected to, or connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event can occur therebetween unless “directly after,” “directly subsequent” or “directly before” is indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first,” “second,” “third,” and so on can be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for describing embodiments.

Further, in a specific situation, a term can be arbitrarily selected by the applicant, and in this situation, the detailed meaning thereof will be described in a corresponding description section. Therefore, the terms used in the description below should be understood based on not simply the name of the terms, but the meaning of the terms and the contents throughout the Detailed Descriptions.

In description of flow of a signal, for example, when a signal is delivered from a node A to a node B, this can include a situation where the signal is transferred from the node A to the node B via another node unless a phrase ‘immediately transferred’ or ‘directly transferred’ is used.

As used herein, the term “display device” can include, in a narrow sense, a display device including a liquid crystal module (LCM), an organic light-emitting diode (OLED) module, or a quantum dot (QD) module including a display panel and a driver for driving the display panel. Moreover, the display device can include, in a broad sense, a set electronic device, a set device or a set apparatus including a complete product or a final product including the LCM, the OLED module, or the QD module such as a laptop computer, a television, a computer monitor, an automotive device, mobile electronic device such as a smartphone or an electronic pad.

Therefore, the display device in accordance with the present disclosure can include, in the narrow sense, a display device itself including, for example, the LCM, the OLED module, QD module, etc., and can include, in a broad sense, the set device as an application product or an end-user device including a complete product or a final product including the LCM, the OLED module, or the QD module.

Moreover, in some situations, the LCM, OLED module, or QD module composed of the display panel and the driver can be expressed as “display device” in a narrow sense. The electronic device as a complete product including the LCM, OLED module or QD module can be expressed as “set device” in a broad sense. For example, the display device in the narrow sense can include a display panel such as a liquid crystal panel, an organic light-emitting display panel, or a quantum dot display panel, and a source PCB as a controller for driving the display panel. The set device in the broad sense can include a display panel such as a liquid crystal panel, an organic light-emitting display panel, or a quantum dot display panel, a source PCB as a controller for driving the display panel, and a set PCB as a set controller that is electrically connected to the source PCB and controls the set device.

As used herein, the display panel can be of any type of the display panels such as a liquid crystal display panel, an organic light emitting diode (OLED) display panel, a quantum dot (QD) display panel, and an electroluminescent display panel, etc. Embodiments are not limited thereto. For example, the display panel can be embodied as a display panel which can be vibrated by a vibrating device according to an embodiment of the present disclosure to generate a sound. A display panel applied to a display device according to an embodiment of the present disclosure is not limited to a shape or a size of the display panel.

Hereinafter, various embodiments of the present disclosure will be described in detail with reference to drawings. All the components of each display device according to all embodiments of the present disclosure are operatively coupled and configured.

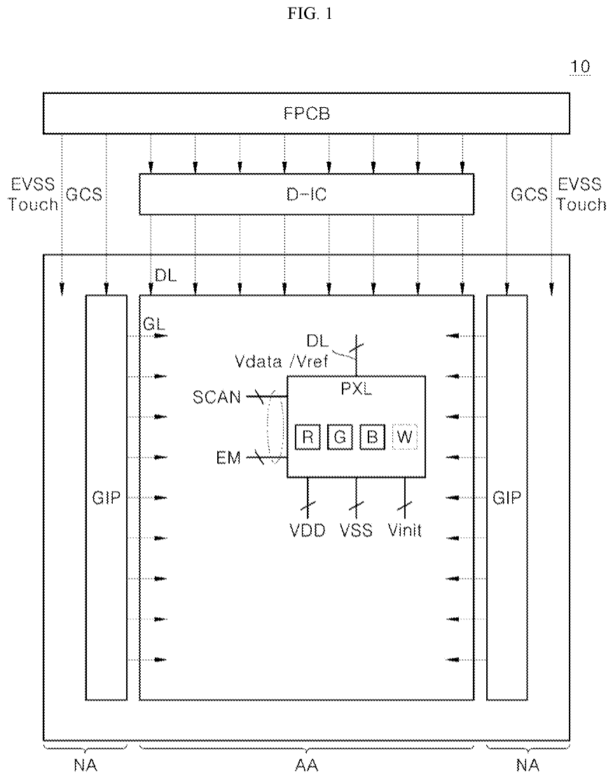

FIG. 1 is a block diagram illustrating a display device according to an embodiment of the present disclosure.

Referring to FIG. 1, a display device 10 can include a plurality of areas. For example, the display device 10 can include one or more display areas AA where an image is displayed, and a pixel PXL can be formed in the display area AA. One or more non-display areas NA in which an image is not displayed can include a driver circuit area and a dam area, and can be disposed on one side of the display area AA. For example, the non-display area NA can be adjacent to one or more sides of the display area AA.

Referring to FIG. 1, the non-display area NA can surround the display area AA of a rectangular shape. However, it should be understood that a shape of the display area AA and a position of the non-display area NA adjacent to the display area AA are not specifically limited to those in the display device 10 as shown in FIG. 1. Each of the display area AA and the non-display area NA can have any shape. Examples of these shapes can include a pentagon, a hexagon, a circle, an oval, etc. An embodiment of the present disclosure is not limited thereto.

The pixel PXL in the display area AA includes sub-pixels. The sub-pixels can display colors such as red (R), green (G), blue (B), and white (W). Moreover, each pixel PXL or sub-pixel can be associated with a pixel circuit including one or more transistor thin-film transistors (TFTs) which are disposed on a substrate of the display device 10. Each pixel circuit can be electrically connected to a gate line GL and a data line DL to communicate with one or more driver circuits, for example, a gate driver GIP and a data driver D-IC disposed in the non-display area NA of the display device 10.

One or more driver circuits can be implemented as TFTs disposed in the non-display area NA as shown in FIG. 1. For example, the gate driver GIP can be implemented using a plurality of TFTs on the substrate of the display device 10. Non-limiting examples of circuits that can be implemented as the TFTs of the substrate include an inverter circuit, a multiplexer, and an ESD (electro-static discharge) circuit. An embodiment of the present disclosure is not limited thereto.

Some driver circuits can be provided as IC (integrated circuit) chips, and can be mounted in the non-display area NA of the display device 10 using a COG (chip-on-glass) or in other similar schemes. Moreover, some driver circuits can be mounted on another substrate, and can be coupled to a connection interface (pads/bumps, pins) disposed in the non-display area NA using a printed circuit board such as a flexible PCB (flexible printed circuit board: FPCB), COF (chip-on-film), TCP (tape-carrier-package) or other suitable schemes.

In embodiments of the present disclosure, at least two different types of TFTs are disposed in a TFT substrate for display. For example, the display panel can include a mix of LTPS TFTs and oxide TFTs, but embodiments are not limited thereto. The types of TFTs employed in a portion of the pixel circuit and a portion of the driver circuit can vary according to requirements of display.

For example, the pixel circuit can be implemented as a TFT (oxide TFT) with an oxide active layer. The driver circuit can be implemented as a TFT (LTPS TFT) with a low-temperature polycrystalline silicon active layer and a TFT (oxide TFT) with an oxide active layer. Unlike the LTPS TFTs, the oxide TFTs do not suffer from pixel-to-pixel threshold voltage Vth variation. A uniform threshold voltage Vth can also be obtained in an array of pixel circuits for display. The uniformity problem of the threshold voltages Vth of the TFTs implementing the driver circuit will have less direct impact on the luminance uniformity of the pixels.

The driver circuits (for example, the gate driver GIP) can have the gate driver IC embedded inside the display panel to reduce the number of driver ICs to achieve cost reduction, and can provide a high-speed scan signal to the display area of the display panel.

Using the driver circuits on the substrate to be implemented as the LTPS TFTs, signals and data can be provided to pixels at a higher clock than that when all TFTs in the TFT panel are embodied as oxide TFTs. Therefore, a display device capable of high-speed operation can be realized. For example, the advantages of the oxide TFT and the LTPS TFT are combined with the design of the TFT panel such that the oxide TFT and the LTPS TFT can be selectively used according to the advantage thereof.

Referring to FIG. 1, a low-potential voltage EVSS, a touch signal TOUCH, and a gate control signal GCS output from the flexible PCB (printed circuit board) (FPCB) are applied to the display panel, and a high-potential voltage is applied to the display panel via the data driver D-IC.

The gate driver GIP can be provided with a SCAN circuit connected to a switching transistor ST1 of the pixel PXL for transmitting a signal for turning on/off the switching transistor ST1 thereto, and an EM circuit connected to a light-emission signal line EM of the pixel PXL.

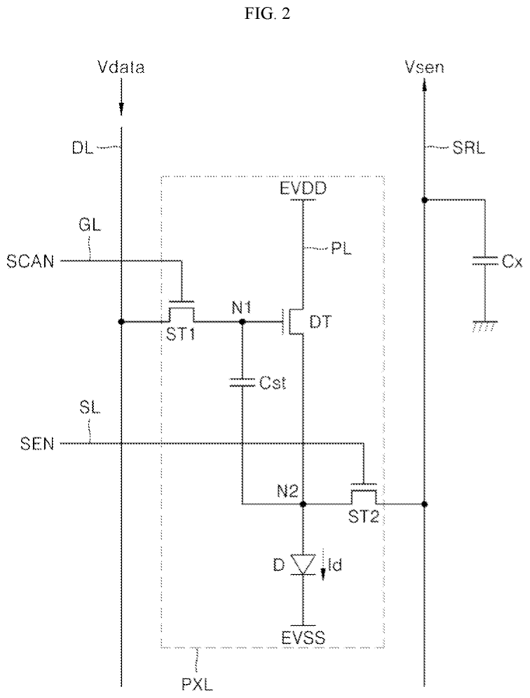

FIG. 2 illustrates a pixel circuit that can be used in embodiments of the present disclosure. Particularly, FIG. 2 illustrates an example in which the display device has a 3T1C structure including three thin-film transistors and one storage capacitor. However, the display device of the present disclosure is not limited to this structure, and can have various structures such as 4T1C, 5T1C, 6T1C, 7T1C, 8T1C, 4T2C, 5T2C, 6T2C, 7T2C, and 8T2C.

Referring to FIG. 2, the display device 10 according to an embodiment of the present disclosure can include the gate line GL, the data line DL, a power line PL, and a sensing line SL. Each sub-pixel SP can include a first switching thin-film transistor ST1, a second switching thin-film transistor ST2, a driving thin-film transistor DT, a light-emitting element D, and a storage capacitor Cst. However, embodiments of the present disclosure are not limited thereto.

The light-emitting element D includes an anode electrode connected to a second node N2, a cathode electrode connected to an input of the low-potential driving voltage EVSS, and a light-emitting element layer disposed between the anode electrode and the cathode electrode. The light-emitting element D can be an organic light-emitting element. However, embodiments of the present disclosure are not limited thereto.

The driving thin-film transistor DT can control current Id flowing through the light-emitting element D based on a voltage difference Vgs between a voltage of a gate and that of a source. The driving thin-film transistor DT can include a gate electrode connected to a first node N1, a drain electrode connected to the power line PL to provide a high-potential driving voltage EVDD thereto, and a source electrode connected to the second node N2.

The storage capacitor Cst is disposed between and connected to the first node N1 and the second node N2. The storage capacitor Cst allows a predefined voltage to be maintained for one frame.

The first switching thin-film transistor ST1 can apply a data voltage Vdata charged in the data line DL to the first node N1 in response to a gate signal SCAN to turn on the driving thin-film transistor DT during an operation of the display panel. In this regard, the first switching thin-film transistor ST1 can include a gate electrode connected to the gate line GL for receiving the gate signal SCAN therefrom, a drain electrode connected to the data line DL for receiving the data voltage Vdata therefrom, and a source electrode connected to the first node N1.

The second switching thin-film transistor ST2 switches a current between the second node N2 and a sensing voltage read-out line SRL in response to a sensing signal SEN such that a source voltage of the second node N2 is stored in a sensing capacitor Cx of the sensing voltage read-out line SRL. The second switching thin-film transistor ST2 switches a current between the second node N2 and the sensing voltage read-out line SRL in response to the sensing signal SEN during an operation of the display panel such that the source voltage of the driving thin-film transistor DT is reset with an initialization voltage Vpre. A gate electrode of the second switching thin-film transistor ST2 is connected to the sensing line SL, a drain electrode thereof is connected to the second node N2, and a source electrode thereof is connected to the sensing voltage read-out line SRL.

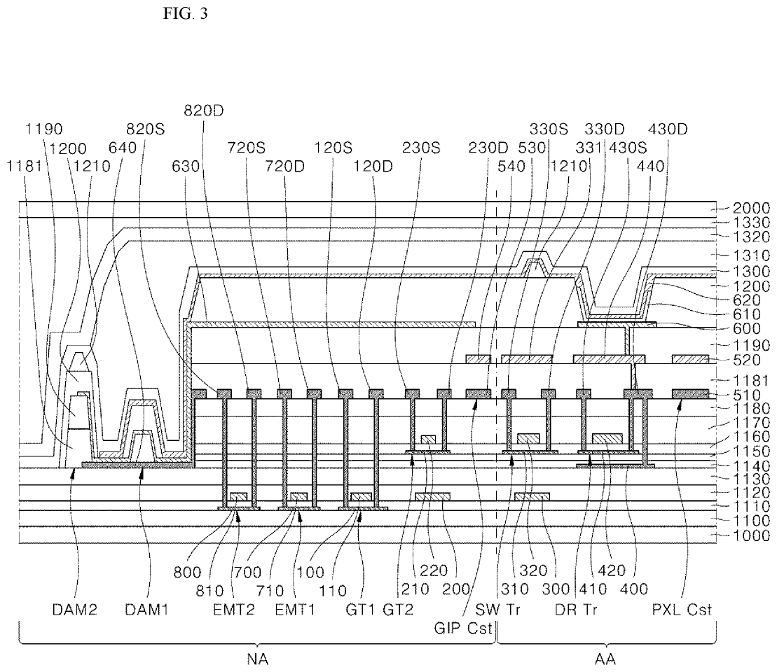

FIG. 3 is a cross-sectional view of a display device according to an embodiment of the present disclosure.

Here, a substrate 1000 of the display device according to an embodiment of the present disclosure can include a first substrate and a second substrate, and an intermediate layer between the first substrate and the second substrate.

The first substrate and the second substrate can be made of at least one of polyimide, polyethersulfone, polyethylene terephthalate, and polycarbonate. Embodiments of the present disclosure are not limited thereto. When the substrate is made of a plastic material, a manufacturing process of the display device can proceed in a state where a support substrate made of glass is disposed under the substrate. Then, after the manufacturing process of the display device is completed, the support substrate can be released. Further, after the support substrate is released, a back plate (or a plate) to support the substrate can be disposed under the substrate. When the substrate is made of a plastic material, moisture can invade into the substrate and then into the thin-film transistor or the light-emitting element layer, which can deteriorate the performance of the display device. The display device according to an embodiment of the present disclosure can be composed of the two substrates, that is, the first substrate and the second substrate made of a plastic material in order to prevent performance degradation of the display device due to the moisture permeation. Further, the intermediate layer made of an inorganic material can be disposed between the first substrate and the second substrate to prevent moisture from penetrating the substrate, thereby can improve the performance reliability of the product. The intermediate layer can be composed of an inorganic film. For example, the intermediate layer can be composed of a single layer of silicon nitride (SiNx) or silicon oxide (SiOx) or a stack of multiple layers made of thereof. However, the present disclosure is not limited thereto.

Referring to FIG. 3, the display device formed on the substrate 1000 can include a plurality of areas. In the present disclosure, the plurality of areas include a display area AA and a non-display area NA. However, embodiments of the present disclosure are not limited thereto.

A buffer layer 1100 can be disposed on one surface of the substrate 1000 and in the display area AA and the non-display area NA. The buffer layer 1100 can improve adhesion between layers formed on the buffer layer 1100 and the substrate 1000, and can perform a role of blocking various types of defect-causing factors, such as alkali components flowing out from the substrate 1000. Further, the buffer layer 1100 can suppress diffusion of moisture or oxygen that has penetrated into the substrate 1000.

The buffer layer 1100 can be composed of a single layer made of silicon nitride (SiNx) or silicon oxide (SiOx) or a stack of multiple layers made thereof. When the buffer layer 1100 is composed of the stack of the multiple layers, the stack can include silicon oxide layers (SiOx) and silicon nitride layers (SiNx) which can be alternately stacked on top of each other.

The buffer layer 1100 can be omitted based on a type and a material of the substrate, a structure and a type of the thin-film transistor, and the like.

Transistors can be formed on the buffer layer 1100 and in the display area AA and the non-display area NA. The transistor of the display area AA can include switching transistors SW Tr and a driving transistor DR Tr for driving the pixel PXL, while the transistor of the non-display area NA can include light-emission transistors EMT1 and EMT2 or gate driver transistors GT1 and GT2 for driving the gate driver GIP.

The driving transistor DR Tr of the display area AA includes a first semiconductor layer 410, a first gate electrode 420, a first source electrode 430S and a first drain electrode 430D. The switching transistor SW Tr of the display area AA includes a second semiconductor layer 310, a second gate electrode 320, a second source electrode 330S, and a second drain electrode 330D. Also, a width of the first gate electrode 420 can be greater than a width of second gate electrode 320, but embodiments are not limited thereto. Also, the first gate electrode 420 and the second gate electrode 320 can be disposed on a same layer.

Each of a third semiconductor layer 100 of the first gate driver transistor GT1, a fourth semiconductor layer 700 of the first light-emission transistor EMT1, and a fifth semiconductor layer 800 of the second light-emission transistor EMT2 disposed in the non-display area NA can be made of a LTPS (Low Temperature Polycrystalline Silicon) semiconductor and disposed on a same layer different. A sixth semiconductor layer 210 of the second gate driver transistor GT2 disposed in the non-display area NA can be made of an oxide semiconductor. Also, the third semiconductor layer 100 of the first gate driver transistor GT1, the fourth semiconductor layer 700 of the first light-emission transistor EMT1 and the fifth semiconductor layer 800 of the second light-emission transistor EMT2 can be disposed on a different layer than the first and second gate electrodes 420, 320.

A first gate insulating layer 1110 can be disposed on the third semiconductor layer 100, the fourth semiconductor layer 700, and the fifth semiconductor layer 800 disposed on the buffer 1100. Since the first gate insulating layer 1110 is disposed between the third semiconductor layer 100, the fourth semiconductor layer 700, and the fifth semiconductor layer 800 and a third gate electrode 110, a fourth gate electrode 710, and a fifth gate electrode 810, the first gate insulating layer 1110 can electrically insulate the third semiconductor layer 100, the fourth semiconductor layer 700, and the fifth semiconductor layer 800 from the third gate electrode 110, the fourth gate electrode 710, and the fifth gate electrode 810 from each other, respectively.

A channel area and source/drain areas connected to source/drain electrodes can be formed in the LTPS semiconductor layer via doping thereof.

The first gate insulating layer 1110 can be made of an insulating inorganic material such as silicon nitride (SiNx) or silicon oxide (SiOx), or an insulating organic material. However, the present disclosure is not limited thereto.

The third gate electrode 110, the fourth gate electrode 710, and the fifth gate electrode 810 can be disposed to overlap the third semiconductor layer 100, the fourth semiconductor layer 700, and the fifth semiconductor layer 800, respectively.

Each of the third gate electrode 110, the fourth gate electrode 710 and the fifth gate electrode 810 can be composed of a single layer or a stack of multiple layers made of any one of silver (Ag), molybdenum (Mo), copper (Cu), titanium (Ti), aluminum (Al), chromium (Cr), nickel (Ni), neodymium (Nd), tungsten (W), and gold (Au) or an alloy thereof. However, the present disclosure is not limited thereto.

A first interlayer insulating layer 1120 and a second insulating layer 1130 can be disposed on the third gate electrode 110, the fourth gate electrode 710, and the fifth gate electrode 810.

Each of the first interlayer insulating layer 1120 and the second insulating layer 1130 can be made of an insulating inorganic material such as silicon nitride (SiNx) or silicon oxide (SiOx), or can be made of an insulating organic material, etc. However, the present disclosure is not limited thereto.

In the same process as a process of forming the third gate electrode 110, the fourth gate electrode 710, and the fifth gate electrode 810 on the first gate insulating layer 1110, a first metal layer 200 and a second metal layer 300 can be respectively formed in areas where the second gate driver transistor GT2 and the switching transistor SW Tr of the display area AA are formed, respectively. Thus, the first metal layer 200 and the second metal layer 300 can be respectively used as lower gates of the second gate driver transistor GT2 and the switching transistor SW Tr of the display area AA. For example, each of the second gate driver transistor GT2 and the switching transistor SW Tr can have a dual gate structure, in which the channel is disposed between two gate electrodes (e.g., a lower gate electrode and an upper gate electrode).

The first metal layer 200 can be electrically connected to a sixth gate electrode 220 of the second gate driver transistor GT2 to drive the second gate driver transistor GT2. The second metal layer 300 can be electrically connected to a second gate electrode 320 of the switching transistor SW Tr of the display area AA to drive the switching transistor SW Tr.

A third insulating layer 1140 can be disposed on the second insulating layer 1130, and a fourth insulating layer 1150 can be further disposed on the third insulating layer 1140.

Each of the third insulating layer 1140 and the fourth insulating layer 1150 can be made of an insulating material such as silicon nitride (SiNx) or silicon oxide (SiOx), or can be made of an insulating organic material, etc. However, embodiments of the present disclosure are not limited thereto.

The first semiconductor layer 410 of the driving transistor DR Tr of the display area AA, the second semiconductor layer 310 of the switching transistor SW Tr of the display area AA, and the sixth semiconductor layer 210 of the second gate driver transistor GT2 of the driver circuit area can be disposed on the fourth insulating layer 1150.

The sixth semiconductor layer 210 can be disposed to overlap the first metal layer 200 disposed on the first gate insulating layer 1110, while the second semiconductor layer 310 can be disposed to overlap the second metal layer 300.

A light-blocking layer 400 can be disposed under the first semiconductor layer 410 of the driving transistor DR Tr.

The light-blocking layer 400 can be disposed between the second insulating layer 1130 and the third insulating layer 1140, and a width of the light-blocking layer 400 can be greater than a width of the first semiconductor layer 410.

The light-blocking layer 400 can prevent light from being directed to the first semiconductor layer 410, and can be connected to the fifth drain electrode 430D to prevent a phenomenon that parasitic carriers are accumulated in the first semiconductor layer 410, resulting in a rapid increase in drain current or to prevent a threshold voltage from changing due to this phenomenon. For example, the light-blocking layer 400 can protect the first semiconductor layer 410.

The light-blocking layer 400 can include at least one of titanium (Ti), molybdenum (Mo), copper (Cu), aluminum (Al), silver (Ag), chromium (Cr), gold (Au), or neodymium (Nd), nickel (Ni), or an alloy thereof. However, embodiments of the present disclosure are not limited thereto.

The driving transistor DR Tr can include the first semiconductor layer 410 made of the metal oxide semiconductor and thus can act as a high mobility element having a mobility of 40 cm²/Vs or greater.

This driving transistor DR Tr can increase the S-factor to reduce the luminance deviation due to a gate voltage distribution.

In this regard, “S-factor” refers to a current-voltage characteristic of a thin-film transistor, and can mean a magnitude of a gate voltage required to increase a drain current by 10 times when the gate voltage below a threshold voltage is applied thereto. The S-factor can be referred to as “subthreshold slope.”

The metal oxide semiconductor can become conductive due to hydrogen. For example, the metal oxide semiconductor can be contaminated or damaged by hydrogen outgassing from other layers or during certain manufacturing steps. This can cause variations in element characteristics, impair image quality, and decrease the lifespan of the device.

Titanium (Ti) has a function of adsorbing hydrogen. Thus, when the light-blocking layer 400 including the titanium (Ti) is disposed around the first semiconductor layer 410 of the driving transistor DR Tr, the light-blocking layer 400 can prevent light from invading the first semiconductor layer 410 of the driving transistor DR Tr, and further prevent hydrogen from invading the first semiconductor layer 410 of the driving transistor DR Tr.

Each of the first semiconductor layer 410, the second semiconductor layer 320, and the sixth semiconductor layer 210 can be made of metal oxide, for example, one of IGZO (Indium-gallium-zinc-oxide), IZO (Indium-zinc-oxide), IGTO (Indium-gallium-tin-oxide) and IGO (Indium-gallium-oxide). However, the present disclosure is not limited thereto.

The conductivity characteristics of the metal oxide semiconductor can be improved by a doping process in which impurities are implanted therein. The metal oxide semiconductor can include a channel area in which a channel along which electrons or holes move is formed, and a source area and a drain area as conductive areas respectively disposed on both opposing sides of the channel area. A source electrode and a drain electrode can be connected to the source area and the drain area, respectively. Channel areas of the first semiconductor layer 410, the second semiconductor layer 320, and the sixth semiconductor layer 210 can be disposed to overlap the first gate electrode 420, the second gate electrode 320, and the sixth gate electrode 320.

A second gate insulating layer 1160 can be disposed between the first semiconductor layer 410, the second semiconductor layer 320, and the sixth semiconductor layer 210 and the first gate electrode 420, the second gate electrode 320, and the sixth gate electrode 320. The second gate insulating layer 1160 can be made of an insulating material such as silicon nitride (SiNx) or silicon oxide (SiOx), or can be made of an insulating inorganic or organic material. However, embodiments of the present disclosure are not limited thereto.

A fifth insulating layer 1170 and a sixth insulating layer 1180 can be disposed on the first gate electrode 420, the second gate electrode 320, and the sixth gate electrode 320. The fifth insulating layer 1170 and the sixth insulating layer 1180 can be made of an insulating material such as silicon nitride (SiNx) or silicon oxide (SiOx), or can be made of an insulating inorganic or organic material. However, embodiments of the present disclosure are not limited thereto.

The first source electrode 430S and the first drain electrode 430D of the driving transistor DR Tr, and the second source electrode 330S and the second drain electrode 330D of the switching transistor SW Tr of the sub-pixel can be formed on the sixth insulating layer 1180 to be connected to the source and drain areas of the first semiconductor layer 410 and the source and drain areas of the second semiconductor layer 310 via contact-holes formed in the second gate insulating layer 1160, the fifth insulating layer 1170, and the sixth insulating layer 1180, respectively.

Further, a third source electrode 120S and a third drain electrode 120D connected to the third semiconductor layer 100 of the first gate driver GT1, a fourth source electrode 720S and a fourth drain electrode 720D connected to the fourth semiconductor layer 700 of the first light-emission transistor EMT1, a fifth source electrode 820S and a fifth drain electrode 820D connected to the fifth semiconductor layer 800 of the second light-emission transistor EMT2, and a sixth source electrode 230S and a sixth drain electrode 230D connected to the sixth semiconductor layer 210 of the second gate driver GT2 can be disposed on the sixth insulating layer 1180 to be connected to the source and drain areas of the third semiconductor layer 100, the source and drain areas of the fourth semiconductor layer 700, the source and drain areas of the fifth semiconductor layer 800, and the source and drain areas of the sixth semiconductor layer 210 via contact-holes formed in the first gate insulating layer 1110, the first insulating layer 1120, the second insulating layer 1130, and the third insulating layer 1140, the fourth insulating layer 1150, the second gate insulating layer 1160, the fifth insulating layer 1170 and the sixth insulating layer 1180, respectively.

A first capacitor electrode 510 of a pixel capacitor PXL Cst can be disposed on one side of the driving transistor DR Tr, while a third capacitor electrode 530 of a gate driver capacitor GIP Cst can be disposed on one side of the second gate driver GT2.

The first source electrode 430S, the first drain electrode 430D, the second source electrode 330S, the second drain electrode 330D, the third source electrode 120S, the third drain electrode 120D, the fourth source electrode 720S, the fourth drain electrode 720D, the fifth source electrode 820S, the fifth drain electrode 820D, the sixth source electrode 230S, and the sixth drain electrode 230D, and the first capacitor electrode 510 and the third capacitor electrode 530 can be disposed on the same layer and can be formed in the same process and include a same material.

Each of the first source electrode 430S, the first drain electrode 430D, the second source electrode 330S, the second drain electrode 330D, the third source electrode 120S, the third drain electrode 120D, the fourth source electrode 720S, the fourth drain electrode 720D, the fifth source electrode 820S, the fifth drain electrode 820D, the sixth source electrode 230S, the sixth drain electrode 230D, the first capacitor electrode 510, and the third capacitor electrode 570 can include at least one of titanium (Ti), molybdenum (Mo), copper (Cu), aluminum (Al), silver (Ag), chromium (Cr), gold (Au), neodymium (Nd), or nickel (Ni) or can be made of an alloy thereof. However, embodiments of the present disclosure are not limited thereto.

Each of the first source electrode 430S, the first drain electrode 430D, the second source electrode 330S, the second drain electrode 330D, the third source electrode 120S, the third drain electrode 120D, the fourth source electrode 720S, the fourth drain electrode 720D, the fifth source electrode 820S, the fifth drain electrode 820D, the sixth source electrode 230S, the sixth drain electrode 230D, the first capacitor electrode 510, and the third capacitor electrode 570 can be composed of at least two layers including a first layer made of titanium (Ti), and a second layer made of at least one of molybdenum (Mo), copper (Cu), aluminum (Al), silver (Ag), chromium (Cr), gold (Au), neodymium (Nd), or nickel (Ni). However, the present disclosure is not limited thereto.

When the pixel capacitor PXL Cst and the gate driver capacitor GIP Cst are disposed on the same layer as a layer in which the source and drain electrodes are disposed, the design freedom of the gate electrode and the semiconductor layer disposed under the pixel capacitor PXL Cst and the gate driver capacitor GIP Cst can be improved.

Further, as the number of layers made of titanium (Ti) increases, the phenomenon that the semiconductor becomes conductive due to the hydrogen in the display panel can be more effectively prevented. Thus, the pixel capacitor PXL Cst and the gate driver capacitor GIP Cst can be made of a material containing titanium (Ti) to adsorb the hydrogen in the display panel to improve the performance of the oxide semiconductor. For example, capacitors including titanium (Ti) can be disposed adjacent to or near the oxide TFTs to help collect any stray hydrogen atoms, in order to better protect the oxide TFTs from hydrogen.

A seventh insulating layer 1181 is disposed on the first source electrode 430S, the first drain electrode 430D, the second source electrode 330S, the second drain electrode 330D, the third source electrode 120S, the third drain electrode 120D, the fourth source electrode 720S, the fourth drain electrode 720D, the fifth source electrode 820S, the fifth drain electrode 820D, the sixth source electrode 230S, the sixth drain electrode 230D, the first capacitor electrode 510 and the third capacitor electrode 530.

The seventh insulating layer 1181 can be made of an insulating material such as silicon nitride (SiNx) or silicon oxide (SiOx), or can be made of an insulating inorganic or organic material. However, embodiments of the present disclosure are not limited thereto.

A second capacitor electrode 520 overlapping the first capacitor electrode 510 of the pixel capacitor PXL Cst, and a fourth capacitor electrode 540 overlapping the third capacitor electrode 530 of the gate driver capacitor GIP Cst can be disposed on the seventh insulating layer 1181.

A connection electrode 440 connected to the first drain electrode 430D of the driving transistor DR Tr can be disposed on the seventh insulating layer 1181 to overlap the first drain electrode 430D. The connection electrode 440 can electrically connect the first drain electrode 430D and an anode electrode 600 to each other.

An auxiliary electrode 331 can be disposed on the seventh insulating layer 1181 at a position overlapping the second source electrode 330S and the second drain electrode 330D of the switching transistor SW Tr.

The auxiliary electrode 331 can be disposed for adsorption of the hydrogen in the display panel, and can be connected to the second source electrode 330S or the second drain electrode 330D, or can not be connected thereto as shown in FIG. 3.

The second capacitor electrode 520, the fourth capacitor electrode 540, the connection electrode 440, and the auxiliary electrode 331 can be disposed on the same layer and can be formed in the same process.

Each of the second capacitor electrode 520, the fourth capacitor electrode 540, the connection electrode 440, and the auxiliary electrode 331 can include at least one of titanium (Ti), molybdenum (Mo), copper (Cu), aluminum (Al), silver (Ag), chromium (Cr), gold (Au), neodymium (Nd), or nickel (Ni), or can be made of an alloy thereof. However, embodiments of the present disclosure are not limited thereto.

Each of the second capacitor electrode 520, the fourth capacitor electrode 540, the connection electrode 440, and auxiliary electrode 331 can be composed of at least two layers including a first layer made of titanium (Ti), and a second layer made of at least one of molybdenum (Mo), copper (Cu), aluminum (Al), silver (Ag), chromium (Cr), gold (Au), neodymium (Nd), or nickel (Ni). However, the present disclosure is not limited thereto.

A first planarization layer 1190 is disposed on the second capacitor electrode 520, the fourth capacitor electrode 540, the connection electrode 440, and the auxiliary electrode 331.

The first planarization layer 1190 can be made of at least one organic insulating material selected among BCB (BenzoCycloButene), acryl resin, epoxy resin, phenolic resin, polyamide resin, and polyimide resin. However, the present disclosure is not limited thereto.

The organic insulating material can be used to planarize steps of an underlying layer.

Referring to FIG. 3, the anode electrode 600 can be disposed on the first planarization layer 1190. The anode electrode 600 can be connected to the connection electrode 440 via a hole formed in the first planarization layer 1190.

A first connection line 630 can be formed on the gate driver transistors GT1 and GT2 or the light-emission transistors EMT1 and EMT2 of the non-display area NA to overlap the driver circuit area including the gate driver transistors GT1 and GT2 or the light-emission transistors EMT1 and EMT2. The first connection line 630 can be formed in the same process as a process of forming the anode electrode 600.

Each of the anode electrode 600 and the first connection line 630 can be made of at least one or more of silver (Ag), aluminum (Al), gold (Au), molybdenum (Mo), tungsten (W), chromium (Cr), lead (Pd), an alloy thereof, indium tin oxide (ITO), or indium zinc oxide (IZO). However, embodiments of the present disclosure are not limited thereto.

A bank 1200 can be disposed on the anode electrode 600, the first connection line 630, and the first planarization layer 1190.

The bank 1200 can distinguish a plurality of sub-pixels from each other, minimize light blurring, and prevent color mixing occurring at various viewing angles.

The bank 1200 can have an opening defined therein to expose a portion of the anode electrode 600 corresponding to a light-emitting area and can overlap with an end portion of the anode electrode 600.

Further, the bank 1200 can overlap a hole formed in the first planarization layer 1900 and a contact-hole formed in the fifth insulating layer 1170 and the sixth insulating layer 1180.

Referring to FIG. 3, the opening of the bank 1200 partially exposing the anode electrode 600 can overlap a hole formed in the first planarization layer 1900 and a hole formed in the fifth insulating layer 1170 and the sixth insulating layer 1180.

The bank 1200 can be made of an inorganic insulating material such as silicon nitride (SiNx) or silicon oxide (SiOx), or can be made of at least one organic insulating material among BCB (BenzoCycloButene), acryl resin, epoxy resin, phenolic resin, polyamide resin, and polyimide resin. However, the present disclosure is not limited thereto.

A spacer 1210 can be further disposed on the bank 1200. The spacer 1210 maintains a gap between the substrate 1000 on which a light-emitting element layer 610 is formed and a higher substrate, thereby minimizing damage to an element inside the display panel when a physical impact from the outside is applied thereto. The spacer 1210 can be made of the same material as that of the bank 1200, and the spacer 1210 and the bank 1200 can be formed simultaneously. However, the present disclosure is not limited thereto.

The light-emitting element layer 610 can be disposed in the opening of the bank 1200 partially exposing the anode electrode 600. The light-emitting element layer 610 can include at least one of a red light-emitting layer, a green light-emitting layer, a blue light-emitting layer, and a white light-emitting layer in order to emit light of a specific color.

When the light-emitting element layer 610 includes the white organic light-emitting layer, the light-emitting element layer 610 can be disposed in the opening of the bank 1200 and over an entire surface of the substrate.

A color filter can be disposed on the light-emitting element layer 610 to convert white light emitted from the white organic light-emitting layer into light of a different color from the white color. The light-emitting element layer 610 can include not only the light-emitting layer, but also a hole injection layer, a hole transport layer, an electron transport layer, and an electron injection layer. However, the present disclosure is not limited thereto.

A cathode electrode 620 can be disposed on the light-emitting element layer 610. The cathode electrode 620 supplies electrons to the light-emitting element layer 610 and can be made of a conductive material having a low work function.

When the display device 10 is of a top emission type, the cathode electrode 620 can be made of a transparent conductive material through which light transmits. For example, the transparent conductive material can include indium tin oxide (ITO), and indium zinc oxide (IZO). However, the present disclosure is not limited thereto.

Alternatively, the cathode electrode 620 can be made of a semi-transmissive conductive material that transmits light therethrough. For example, the cathode electrode 230 can be made of at least one or more of LiF/Al, CsF/Al, Mg:Ag, Ca/Ag, Ca:Ag, LiF/Mg:Ag, LiF/Ca/Ag, and LiF/Ca:Ag. However, the present disclosure is not limited thereto.

When the display device 10 is of a bottom emission type, the cathode electrode 620 can act as a reflective electrode that reflects light therefrom and can be made of an opaque conductive material. For example, the cathode electrode 620 can be made of at least one of silver (Ag), aluminum (Al), gold (Au), molybdenum (Mo), tungsten (W), chromium (Cr), or an alloy thereof.

In the non-display area NA of the display device 10, a driver circuit area and a side end area including a dam area in which a plurality of dams are disposed are disposed. The side end area of the non-display area NA can be an area where the display device 10 is sealed using a connection portion where the cathode electrode 620 and the EVSS line are electrically connected to each other, an encapsulation layer, and a plurality of dams.

The buffer layer 1100, the first gate insulating layer 1110, the first insulating layer 1120, and the second insulating layer 1130 disposed on the substrate 1000 can extend to be disposed in the side end area.

Lines (e.g., wires or wire traces) can be disposed in the side end area so that the power voltage and the touch signal applied from the FPCB of the display device 10 are applied to the display panel via the lines.

A second connection line 640 can be disposed on the second insulating layer 1130.

The second connection line 640, the first source electrode 430S, the first drain electrode 430D, the second source electrode 330S, the second drain electrode 330D, the third source electrode 120S, the third drain electrode 120D, the fourth source electrode 720S, the fourth drain electrode 720D, the fifth source electrode 820S, the fifth drain electrode 820D, the sixth source electrode 230S, and the sixth drain electrode 230D and the first capacitor electrode 510 and the third capacitor electrode 530 can be disposed on the same layer and can be formed in the same process and include a same material. However, embodiments of the present disclosure are not limited thereto.

The plurality of dams can be disposed in the side end area of the non-display area NA. The present disclosure illustrates that plurality of dams include a first dam DAM1 and a second dam DAM2. However, the present disclosure is not limited thereto.

In order to prevent leakage of a second encapsulation layer 1310 made of the organic material, each of the first dam DAM1 and the second dam DAM2 can have a stack structure in which at least one insulating layer can be stacked. However, embodiments of the present disclosure are not limited thereto.

The first dam DAM1 and the second dam DAM2 can have a first height and a second height, respectively, and can surround the display area AA.

The second height is greater than the first height. Thus, even when the material of the second encapsulation layer 1310 flows over the first dam DAM1, the second dam DAM2 can block the material of the second encapsulation layer 1310.

The first dam DAM1 and the second dam DAM2 can be composed of a portion of the seventh insulating layer 1181, a portion of the first planarization layer 1190, a portion of the bank 1200, and a portion of the spacer 1210.

The second connection line 640 can extend to be disposed under the portion of the seventh insulating layer 1181 constituting the first dam DAM1 and the second dam DAM2.

The first connection line 630 can be disposed between the portion of the seventh insulating layer 1181 constituting the first dam DAM1 and the portion of the first planarization layer 1190 constituting the first dam DAM1, and can be disposed between the portion of the first planarization layer 1190 constituting the second dam DAM2 and the portion of the bank 1200 constituting the second dam DAM2. The first connection line 630 can be disposed on a side surface and an upper surface of the portion of the seventh insulating layer 1181 constituting the first dam DAM1, and can be disposed on a side surface of the seventh insulating layer 1181 constituting the second dam DAM2, and a side surface and an upper surface of the portion of the first planarization layer 1190 constituting the second dam DAM2.

In an area between the first dam DAM1 and the second dam DAM2 and an area in which the seventh insulating layer 1181 and the first planarization layer 1190 are not formed, the first connection line 630, the second connection line 640, and the cathode electrode 620 can contact each other and thus can be electrically connected to each other.

A capping layer can be disposed on the cathode electrode 620. The capping layer can be embodied as an organic or inorganic film that protects the cathode electrode 620 and improves external light efficiency. Alternatively, the capping layer can be composed of an inorganic film and can be made of a metal material such as LiF, and the capping layer can further include an organic film. However, embodiments of the present disclosure are not limited thereto.

An encapsulation can be disposed on the cathode electrode 620 and the capping layer. The encapsulation can protect the display device 10 from external moisture, oxygen, or foreign matter. For example, the encapsulation can prevent penetration of oxygen and moisture from the outside into a light-emitting material and an electrode material in order to prevent oxidation of the light-emitting material and the electrode material.

The encapsulation can be made of a transparent material so that light emitted from the light-emitting element layer 610 transmits therethrough.

The encapsulation can include a first encapsulation layer 1300, the second encapsulation layer 1310, and a third encapsulation layer 1320 to prevent penetration of moisture or oxygen into the light-emitting material and the electrode material. However, embodiments of the present disclosure are not limited thereto.

The first encapsulation layer 1300, the second encapsulation layer 1310, and the third encapsulation layer 1320 can be sequentially stacked. However, embodiments of the present disclosure are not limited thereto.

Each of the first encapsulation layer 1300 and the third encapsulation layer 1320 can be made of at least one inorganic material selected from among silicon nitride (SiNx), silicon oxide (SiOx), and aluminum oxide (AlyOz). However, the present disclosure is not limited thereto.

The second encapsulation layer 1310 can cover foreign substances or particles that can occur in the manufacturing process. Further, the second encapsulation layer 1310 can planarize a surface of the first encapsulation layer 1300.

The second encapsulation layer 1310 can be made of an organic material, for example, silicon oxycarbon (SiOCz), epoxy, polyimide, polyethylene, or acrylate-based polymer. However, the present disclosure is not limited thereto.

A cover window 2000 can be disposed on the third encapsulation layer 1320.

The third encapsulation layer 1320 and the cover window 2000 can be bonded to each other via an adhesive layer 1330 disposed between the third encapsulation layer 1320 and the cover window 2000. A touch electrode and a touch insulating layer for a touch operation can be further formed between the third encapsulation layer 1320 and the cover window 2000.

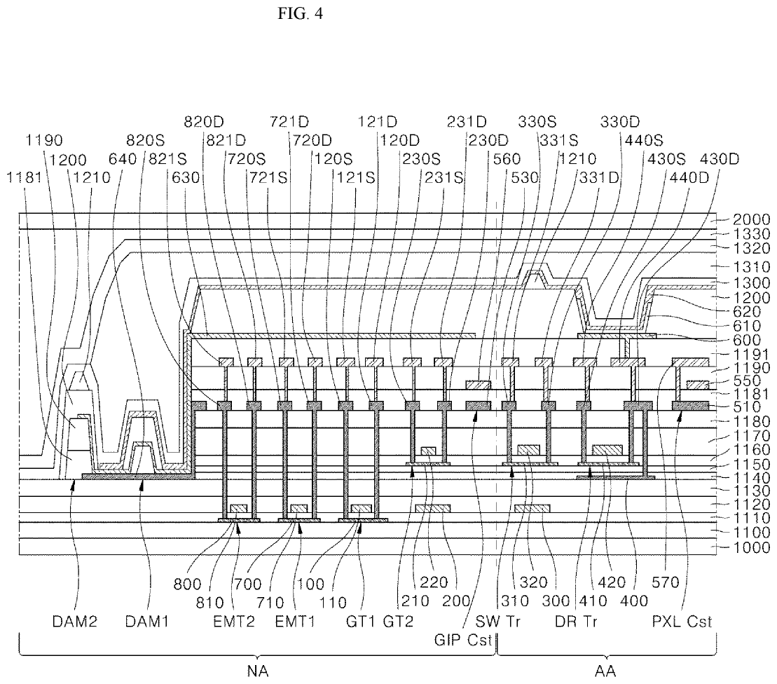

FIG. 4 is a cross-sectional view of a display device according to another embodiment of the present disclosure.

In describing this embodiment of the present disclosure, description of the same as or corresponding components thereof as or to those of the previous embodiment is omitted or simplified.

Referring to FIG. 4, the seventh insulating layer 1181 is disposed on the first source electrode 430S, the first drain electrode 430D, the second source electrode 330S, the second drain electrode 330D, the third source electrode 120S, the third drain electrode 120D, the fourth source electrode 720S, the fourth drain electrode 720D, the fifth source electrode 820S, the fifth drain electrode 820D, the sixth source electrode 230S, and the sixth drain electrode 230D, the first capacitor electrode 510 and the third capacitor electrode 530.

The seventh insulating layer 1181 can be made of an insulating material such as silicon nitride (SiNx) or silicon oxide (SiOx), or can be made of an insulating organic material. However, embodiments of the present disclosure are not limited thereto.

A second capacitor electrode 550 overlapping the first capacitor electrode 510 and a fourth capacitor electrode 560 overlapping the third capacitor electrode 530 can be disposed on the seventh insulating layer 1181.

Each of the second capacitor electrode 550 and the fourth capacitor electrode 560 can include at least one of titanium (Ti), molybdenum (Mo), copper (Cu), aluminum (Al), silver (Ag), chromium (Cr), gold (Au), neodymium (Nd), or nickel (Ni), or can be made of an alloy thereof. However, embodiments of the present disclosure are not limited thereto.

Each of the second capacitor electrode 550 and the fourth capacitor electrode 560 can be composed of at least two layers including a first layer made of titanium (Ti), and a second layer made of at least one of molybdenum (Mo), copper (Cu), aluminum (Al), silver (Ag), chromium (Cr), gold (Au), neodymium (Nd), and nickel (Ni). However, the present disclosure is not limited thereto.

The first planarization layer 1190 can be disposed on the second capacitor electrode 550 and the fourth capacitor electrode 560. The first planarization layer 1190 can be made of at least one organic insulating material selected among BCB (BenzoCycloButene), acryl resin, epoxy resin, phenolic resin, polyamide resin, and polyimide resin. However, the present disclosure is not limited thereto.

A first electrode 570 connected to the first capacitor electrode 510 via a contact-hole formed in the first planarization layer 1190 and the seventh insulating layer 1181 can be disposed.

A connection electrode 440D can overlap with the first drain electrode 430D of the driving transistor DR Tr and be connected to the first drain electrode 430D via a contact-hole formed in the first planarization layer 1190 and the seventh insulating layer 1181. A first source auxiliary electrode 440S can overlap the first source electrode 430S thereof and can be connected to the first source electrode 430S via a contact-hole formed in the first planarization layer 1190 and the seventh insulating layer 1181.

A second drain auxiliary electrode 331D can overlap with the second drain electrode 330D of the switching transistor SW Tr and can be connected to the second drain electrode 330D via a contact-hole formed in the first planarization layer 1190 and the seventh insulating layer 1181. A second source auxiliary electrode 331S can overlap the second source electrode 330S thereof and can be connected to the second source electrode 330S via a contact-hole formed in the first planarization layer 1190 and the seventh insulating layer 1181.

A third drain auxiliary electrode 121D can overlap with the third drain electrode 120D of the first gate driver transistor GT1 and can be connected to the third drain electrode 120D via a contact-hole formed in the first planarization layer 1190 and the seventh insulating layer 1181. A third source auxiliary electrode 121S can overlap the third source electrode 120S thereof and can be connected to the third source electrode 120S via a contact-hole formed in the first planarization layer 1190 and the seventh insulating layer 1181.

A sixth drain auxiliary electrode 221D can overlap with the sixth drain electrode 220D of the second gate driver transistor GT2 and can be connected to the sixth drain electrode 220D via a contact-hole formed in the first planarization layer 1190 and the seventh insulating layer 1181. A sixth source auxiliary electrode 221S can overlap the sixth source electrode 220S thereof and can be connected to the sixth source electrode 220S via a contact-hole formed in the first planarization layer 1190 and the seventh insulating layer 1181.

A fourth drain auxiliary electrode 721D can overlap the fourth drain electrode 720D of the first light-emission transistor EMT1 and can be connected to the fourth drain electrode 720D via a contact-hole formed in the first planarization layer 1190 and the seventh insulating layer 1181. A fourth source auxiliary electrode 721S can overlap the fourth source electrode 720S thereof and can be connected to the fourth source electrode 720S via a contact-hole formed in the first planarization layer 1190 and the seventh insulating layer 1181.

A fifth drain auxiliary electrode 821D can overlap with the fifth drain electrode 820D of the second light-emission transistor EMT2 and can be connected to the fifth drain electrode 820D via a contact-hole formed in the first planarization layer 1190 and the seventh insulating layer 1181. A fifth source auxiliary electrode 821S can overlap with the fifth source electrode 820S thereof and can be connected to the fifth source electrode 820S via a contact-hole formed in the first planarization layer 1190 and the seventh insulating layer 1181.

Each of the first electrode 570, the connection electrode 440D, the first source auxiliary electrode 440S, the second drain auxiliary electrode 331D, the second source auxiliary electrode 331S, the third drain auxiliary electrode 121D, the third source auxiliary electrode 121S, the sixth drain auxiliary electrode 221D, the sixth source auxiliary electrode 221S, the fourth drain auxiliary electrode 721D, the fourth source auxiliary electrode 721S, the fifth drain auxiliary electrode 821D, and the fifth source auxiliary electrode 821S can include at least one of titanium (Ti), molybdenum (Mo), copper (Cu), aluminum (Al), silver (Ag), chromium (Cr), gold (Au), neodymium (Nd), nickel (Ni), or an alloy thereof. However, the present disclosure is not limited thereto.

Alternatively, each of the first electrode 570, the connection electrode 440D, the first source auxiliary electrode 440S, the second drain auxiliary electrode 331D, the second source auxiliary electrode 331S, the third drain auxiliary electrode 121D, the third source auxiliary electrode 121S, the sixth drain auxiliary electrode 221D, the sixth source auxiliary electrode 221S, the fourth drain auxiliary electrode 721D, the fourth source auxiliary electrode 721S, the fifth drain auxiliary electrode 821D, and the fifth source auxiliary electrode 821S can be composed of at least two or more layers including a first layer made of titanium (Ti), and a second layer made of at least one of molybdenum (Mo), copper (Cu), aluminum (Al), silver (Ag), chromium (Cr), gold (Au), neodymium (Nd), and nickel (Ni). However, the present disclosure is not limited thereto.

The first planarization layer 1190 can be disposed on the second capacitor electrode 550, and the first electrode 570 can be disposed on the first planarization layer 1190, such that a capacitor area size can be increased.

The first source auxiliary electrode 440S, the second drain auxiliary electrode 331D, the second source auxiliary electrode 331S, the third auxiliary drain electrode 121D, the third source auxiliary electrode 121S, the sixth drain auxiliary electrode 221D, the sixth source auxiliary electrode 221S, the fourth drain auxiliary electrode 721D, the fourth source auxiliary electrode 721S, the fifth drain auxiliary electrode 821D, and the fifth source auxiliary electrode 821S can allow electrical resistances of the corresponding source electrodes and the corresponding drain electrodes respectively connected thereto to be lowered. For example, each electrode from the embodiment in FIG. 3 can be paired with a corresponding auxiliary electrode as shown in FIG. 4, which can reduce the electrical resistance and reduce power consumption. Also, each of the auxiliary electrodes can include a material for adsorbing hydrogen (e.g., titanium (Ti), etc.), which can also help protect the oxide TFTs. For example, oxide TFTs and LTPS TFTs can be provided on the same substrate and the oxides TFTs can be securely protected. Thus, the auxiliary electrodes can provide dual functions of reducing power consumption and protecting the oxide TFTs. For design optimization, at least one of the first source auxiliary electrode 440S, the second drain auxiliary electrode 331D, the second source auxiliary electrode 331S, the third drain auxiliary electrode 121D, the third source electrode auxiliary 121S, the sixth auxiliary electrode 221D, the sixth source auxiliary electrode 221S, the fourth drain auxiliary electrode 721D, the fourth source auxiliary electrode 721S, the fifth drain auxiliary electrode 821D, and the fifth source auxiliary electrode 821S can be omitted.

A second planarization layer 1191 can be disposed on the first electrode 570, connection electrode 440D, the first source auxiliary electrode 440S, the second drain auxiliary electrode 331D, the second source auxiliary electrode 331S, the third drain auxiliary electrode 121D, the third source auxiliary electrode 121S, the sixth drain auxiliary electrode 221D, the sixth source auxiliary electrode 221S, the fourth drain auxiliary electrode 721D, the fourth source auxiliary electrode 721S, the fifth drain auxiliary electrode 821D, and the fifth source auxiliary electrode 821S.

The second planarization layer 1191 can be made of at least one organic insulating material selected among BCB (BenzoCycloButene), acryl resin, epoxy resin, phenolic resin, polyamide resin, and polyimide resin. However, the present disclosure is not limited thereto. For example, the organic insulating material can be used to planarize steps of an underlying layer. That is, the second planarization layer 1191 made of the organic insulating material can have a planarized top surface even when a layer disposed under the second planarization layer 1191 has steps.

Referring to FIG. 4, the anode electrode 600 can be disposed on the second planarization layer 1191. The anode electrode 600 can be connected to the connection electrode 440D via a hole formed in the second planarization layer 1191.

The first connection line 630 can be formed in the same process as a process of forming the anode electrode 600 on the gate driver transistors GT1 and GT2 or the light-emission transistors EMT1 and EMT2 of the non-display area NA.

A display device according to an embodiment of the present disclosure can be described as follows.

One aspect of the present disclosure provides a display device comprising: a substrate including a display area and a non-display area disposed around the display area; a first transistor disposed in the display area and including a first semiconductor layer, a first gate electrode, a first source electrode, and a first drain electrode; a driver circuit area and a dam area disposed in the non-display area; a second transistor disposed in the driver circuit area and including a second semiconductor layer, a second gate electrode, a second source electrode, and a second drain electrode; a first insulating layer disposed on the first transistor and the second transistor; a first capacitor disposed in the display area; and a second capacitor disposed in the driver circuit area, in which the first capacitor includes a first capacitor electrode disposed on the first insulating layer, in which the second capacitor includes a second capacitor electrode disposed on the first insulating layer.

In some implementations of the display device of the present disclosure, the first capacitor further includes a third capacitor electrode disposed under the first insulating layer, in which the second capacitor further includes a fourth capacitor electrode disposed under the first insulating layer.

In some implementations of the display device of the present disclosure, the display device further comprises: a first planarization layer disposed on the first insulating layer; an anode electrode disposed on the first planarization layer and in the display area; and a first connection line disposed on the first planarization layer and in the non-display area.

In some implementations of the display device of the present disclosure, the first connection line overlaps with the driver circuit area.

In some implementations of the display device of the present disclosure, the display device further comprises a third transistor disposed in the display area, in which the third transistor includes a third semiconductor layer, a third gate electrode, a third source electrode, and a third drain electrode.

In some implementations of the display device of the present disclosure, the display device further comprises: a first metal layer disposed on the first insulating layer and overlapping a portion of the first transistor; and a second metal layer disposed on the first insulating layer and overlapping a portion of the third transistor.

In some implementations of the display device of the present disclosure, each of the first metal layer, the second metal layer, and the first capacitor electrode includes at least one of titanium (Ti), molybdenum (Mo), copper (Cu), aluminum (Al), silver (Ag), chromium (Cr), gold (Au), neodymium (Nd), or nickel (Ni), or is made of an alloy thereof.

In some implementations of the display device of the present disclosure, each of the first metal layer, the second metal layer, and the first capacitor electrode is composed of at least two layers including a first layer made of titanium (Ti), and a second layer made of at least one of molybdenum (Mo), copper (Cu), aluminum (Al), silver (Ag), chromium (Cr), gold (Au), neodymium (Nd), or nickel (Ni).

In some implementations of the display device of the present disclosure, the display device further comprises: a first planarization layer disposed on the first insulating layer; and an anode electrode disposed on the first planarization layer and in the display area, in which the first metal layer electrically connects the first drain electrode of the first transistor and the anode electrode to each other.

In some implementations of the display device of the present disclosure, the display device further comprises a fourth transistor disposed in the driver circuit area, in which the fourth transistor includes a fourth semiconductor layer, a fourth gate electrode, a fourth source electrode, and a fourth drain electrode.

In some implementations of the display device of the present disclosure, the display device further comprises: a third metal layer disposed on the first insulating layer and overlapping a portion of the second transistor; and a fourth metal layer disposed on the first insulating layer and overlapping a portion of the fourth transistor.

In some implementations of the display device of the present disclosure, the second metal layer is connected to the third source electrode and the third drain electrode of the third transistor, in which the third metal layer is connected to the second source electrode and the second drain electrode of the second transistor, in which the fourth metal layer is connected to the fourth source electrode and the fourth drain electrode of the fourth transistor.

In some implementations of the display device of the present disclosure, each of the third metal layer and the fourth metal layer includes at least one of titanium (Ti), molybdenum (Mo), copper (Cu), aluminum (Al), silver (Ag), chromium (Cr), gold (Au), neodymium (Nd), or nickel (Ni), or is made of an alloy thereof.

In some implementations of the display device of the present disclosure, each of the third metal layer and the fourth metal layer is composed of at least two layers including a first layer made of titanium (Ti), and a second layer made of at least one of molybdenum (Mo), copper (Cu), aluminum (Al), silver (Ag), chromium (Cr), gold (Au), neodymium (Nd), or nickel (Ni).

In some implementations of the display device of the present disclosure, each of the first semiconductor layer, the second semiconductor layer, and the third semiconductor layer is made of an oxide semiconductor, in which the fourth semiconductor layer is made of a polycrystalline silicon semiconductor.

In some implementations of the display device of the present disclosure, the second capacitor electrode, the first source electrode, the first drain electrode, the second source electrode, and the second drain electrode are disposed on the same layer and are made of the same material.

In some implementations of the display device of the present disclosure, the first metal layer, the second metal layer, and the first capacitor electrode are disposed on the same layer.

In some implementations of the display device of the present disclosure, the display device further comprises a second insulating layer disposed between the first insulating layer and the first metal layer, the second metal layer, the third metal layer, and the fourth metal layer.

In some implementations of the display device of the present disclosure, the first capacitor is disposed between the first insulating layer and the second insulating layer.

In some implementations of the display device of the present disclosure, the display device further comprises a light-blocking layer disposed under the first semiconductor layer and overlapping the first semiconductor layer, in which the light-blocking layer is electrically connected to the first drain electrode.

In some implementations of the display device of the present disclosure, the display device further comprises: a light-emitting layer disposed on the anode electrode; and a cathode electrode disposed on the light-emitting layer, in which the first connection line is electrically connected to the cathode electrode in the dam area.

In some implementations of the display device of the present disclosure, the display device further comprises a second connection line electrically connected to the first connection line in the dam area.

Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display device comprising:
a substrate including a display area and a non-display area disposed adjacent to the display area;
a first transistor disposed in the display area, the first transistor including a first semiconductor layer, a first gate electrode, a first source electrode, and a first drain electrode;
a driver circuit area and a dam area disposed in the non-display area;
a second transistor disposed in the driver circuit area, the second transistor including a second semiconductor layer, a second gate electrode, a second source electrode, and a second drain electrode;
a first insulating layer disposed on the first transistor and the second transistor;
a first capacitor disposed in the display area; and
a second capacitor disposed in the driver circuit area,
wherein the first capacitor includes a first capacitor electrode disposed on the first insulating layer, and
wherein the second capacitor includes a second capacitor electrode disposed on the first insulating layer.

2. The display device of claim 1, wherein the first capacitor further includes a third capacitor electrode disposed under the first insulating layer, and
wherein the second capacitor further includes a fourth capacitor electrode disposed under the first insulating layer.

3. The display device of claim 2, wherein the second capacitor electrode, the first source electrode, the first drain electrode, the second source electrode, and the second drain electrode are disposed on a same layer and are made of a same material.

4. The display device of claim 1, wherein the display device further comprises:
a first planarization layer disposed on the first insulating layer;
an anode electrode disposed on the first planarization layer and in the display area; and
a first connection line disposed on the first planarization layer and in the non-display area.

5. The display device of claim 4, wherein the first connection line overlaps with the driver circuit area.

6. The display device of claim 4, wherein the display device further comprises:
a light-emitting layer disposed on the anode electrode; and
a cathode electrode disposed on the light-emitting layer,
wherein the first connection line is electrically connected to the cathode electrode in the dam area.

7. The display device of claim 6, wherein the display device further comprises a second connection line electrically connected to the first connection line in the dam area.

8. The display device of claim 1, wherein the display device further comprises a third transistor disposed in the display area,
wherein the third transistor includes a third semiconductor layer, a third gate electrode, a third source electrode, and a third drain electrode.

9. The display device of claim 8, wherein the display device further comprises:
a first metal layer disposed on the first insulating layer and overlapping with a portion of the first transistor; and
a second metal layer disposed on the first insulating layer and overlapping with a portion of the third transistor.

10. The display device of claim 9, wherein each of the first metal layer, the second metal layer, and the first capacitor electrode includes at least one of titanium (Ti), molybdenum (Mo), copper (Cu), aluminum (Al), silver (Ag), chromium (Cr), gold (Au), neodymium (Nd), or nickel (Ni), or is made of an alloy thereof.

11. The display device of claim 9, wherein each of the first metal layer, the second metal layer, and the first capacitor electrode is composed of at least two layers including a first layer made of titanium (Ti), and a second layer made of at least one of molybdenum (Mo), copper (Cu), aluminum (Al), silver (Ag), chromium (Cr), gold (Au), neodymium (Nd), or nickel (Ni).

12. The display device of claim 9, wherein the display device further comprises:
a first planarization layer disposed on the first insulating layer; and
an anode electrode disposed on the first planarization layer and in the display area,
wherein the first metal layer electrically connects the first drain electrode of the first transistor with the anode electrode.

13. The display device of claim 12, wherein the display device further comprises a fourth transistor disposed in the driver circuit area,
wherein the fourth transistor includes a fourth semiconductor layer, a fourth gate electrode, a fourth source electrode, and a fourth drain electrode.

14. The display device of claim 13, wherein the display device further comprises:
a third metal layer disposed on the first insulating layer, the third metal layer overlapping with a portion of the second transistor; and
a fourth metal layer disposed on the first insulating layer, the fourth metal layer overlapping with a portion of the fourth transistor.

15. The display device of claim 14, wherein the second metal layer is connected to the third source electrode and the third drain electrode of the third transistor,
wherein the third metal layer is connected to the second source electrode and the second drain electrode of the second transistor, and
wherein the fourth metal layer is connected to the fourth source electrode and the fourth drain electrode of the fourth transistor.

16. The display device of claim 14, wherein each of the third metal layer and the fourth metal layer includes at least one of titanium (Ti), molybdenum (Mo), copper (Cu), aluminum (Al), silver (Ag), chromium (Cr), gold (Au), neodymium (Nd), or nickel (Ni), or is made of an alloy thereof.

17. The display device of claim 14, wherein each of the third metal layer and the fourth metal layer is composed of at least two layers including a first layer made of titanium (Ti), and a second layer made of at least one of molybdenum (Mo), copper (Cu), aluminum (Al), silver (Ag), chromium (Cr), gold (Au), neodymium (Nd), or nickel (Ni).

18. The display device of claim 14, wherein the display device further comprises a second insulating layer disposed between the first insulating layer and the first, second, third and fourth metal layers.

19. The display device of claim 18, wherein the first capacitor is disposed between the first insulating layer and the second insulating layer.

20. The display device of claim 9, wherein the first metal layer, the second metal layer, and the first capacitor electrode are disposed on a same layer.

21. The display device of claim 13, wherein each of the first semiconductor layer, the second semiconductor layer, and the third semiconductor layer is made of an oxide semiconductor, and
wherein the fourth semiconductor layer is made of a polycrystalline silicon semiconductor.

22. The display device of claim 1, wherein the display device further comprises a light-blocking layer disposed under the first semiconductor layer, the light blocking layer overlapping with the first semiconductor layer,
wherein the light-blocking layer is electrically connected to the first drain electrode.

23. A display device comprising:
a first oxide transistor disposed in a display area of a substrate, the first transistor including a first oxide semiconductor layer, a first gate electrode, a first source electrode and a first drain electrode;
a second polycrystalline silicon transistor disposed a non-display area of the substrate, the second transistor including a second polycrystalline silicon semiconductor layer, a second gate electrode, a second source electrode and a second drain electrode;
a first insulating layer disposed across the first oxide transistor and the second polycrystalline silicon transistor; and
at least one capacitor disposed on the first insulating layer,
wherein the at least one capacitor includes a material configured to absorb hydrogen.

24. The display device of claim 23, wherein the at least one capacitor includes:
a first capacitor disposed in the display area; and
a second capacitor disposed in the non-display area,
wherein the first capacitor includes a first capacitor electrode disposed on the first insulating layer, and
wherein the second capacitor includes a second capacitor electrode disposed on the first insulating layer.

25. The display device of claim 24, wherein the first oxide transistor is disposed between the first capacitor in the display area and the second capacitor in the non-display area.

26. The display device of claim 24, wherein the first source electrode, the first drain electrode, the second source electrode, the second drain electrode, the first capacitor electrode of the first capacitor and the second capacitor electrode of the second capacitor are disposed on a same layer.

27. The display device of claim 26, wherein the first source electrode, the first drain electrode, the second source electrode, the second drain electrode, the first capacitor electrode of the first capacitor and the second capacitor electrode of the second capacitor include a same material configured to absorb hydrogen.

28. The display device of claim 24, further comprising a second insulating layer disposed on the first insulating layer,
wherein each of the first source electrode, the first drain electrode, the second source electrode and the second drain electrode is connected to a corresponding auxiliary electrode disposed on the second insulating layer.

29. The display device of claim 28, wherein the corresponding auxiliary electrodes for the first source electrode, the first drain electrode, the second source electrode and the second drain electrode are made of a same material configured to absorb hydrogen.
